(19) United States
(12) Patent Application Publication
(10) Pub. No.: US 2026/0311758 A1
(43) Pub. Date: Oct. 8, 2026

(54) RANDOM CODE GENERATOR, FABRICATING METHOD THEREOF AND DEVICE APPLYING THE SAME

(71) Applicant: United Microelectronics Corp., Hsinchu (TW)

(72) Inventors: Chung-Hao CHEN, Toyuan City (TW); Cheng-Hsiao LAI, Chiayi County (TW)

(21) Appl. No.: 19/201,991

(22) Filed: May 8, 2025

(30) Foreign Application Priority Data
Apr. 8, 2025 (TW) 114113168

(51) Int. Cl. G11C 13/00

(52) U.S. Cl. CPC G11C 13/004; G11C 13/0069; G11C 2013/0054

(57) ABSTRACT

A random code generator includes: at least one resistive switch element, a control circuit and a logic circuit. The control circuit is electrically connected to the at least one resistive switch element and is used to perform a forming step on the at least one resistive switch element; perform a writing step on the at least one resistive switch element with a preset voltage; and perform two resistance reading steps on the at least one resistive switch element to obtain a first read data and a second read data respectively. The logic circuit is electrically connected to the control circuit, and is used to perform logical operations to compare the first read data and the second read data, thereby generating a random code.

This application claims the benefit of Taiwan Application Serial No. 114113168 filed at Apr. 8, 2025 the subject matter of which is incorporated herein by reference.

### BACKGROUND

### Technical Field

The disclosure relates to a semiconductor device and the method for fabricating the same, and more particularly to a random code generator and the method for fabricating the same.

### Description of Background

With the popularization of Internet of Things (IOT) technology, more and more data can be stored and shared in digital form because Internet devices (such as mobile communication devices, sensors installed on the devices and their built-in software) can be connected to each other through the Internet. However, while providing the convenience of information integration, it also brings higher information security risks. Therefore, the security of Internet devices and the networks they are connected to gets more and more attention.

Physically unclonable function (PUF) technology is a new method to protect the data stored in semiconductor devices (or semiconductor chips). Generally, the PUF technology can obtain a unique random code based on the manufacturing processing variation of an individual semiconductor device (or semiconductor chip). Since this unique random code cannot be copied, thus it can be used as a unique identification code (ID code) to identify the semiconductor device (or semiconductor chip), and to prevent the data stored in the semiconductor device (or semiconductor chip) from being stolen, so as to provide higher information security protection.

### SUMMARY

One aspect of the present disclosure is to provide a random code generator, wherein the random code generator includes at least one resistive switch element, a control circuit and a logic circuit. The control circuit is electrically connected to the at least one resistive switch element and is used to perform a forming step on the at least one resistive switch element; to perform a writing step on the at least one resistive switch element with a preset voltage; and to perform two resistance reading steps on the at least one resistive switch element to obtain a first read data and a second read data respectively. The logic circuit is electrically connected to the control circuit and is used for performing a logic operation to compare the first read data with the second read data, thereby generating a random code.

Another aspect of the present disclosure is to provide a method for fabricating a random code generator, wherein the method includes steps as follows: At least one resistive switch element is provided. A control circuit is then provided to electrically connected to the at least one resistive switch element for performing a forming step on the at least one resistive switch element; performing a writing step on the at least one resistive switch element with a preset voltage; and performing two resistance reading steps on the at least one resistive switch element to obtain a first read data and a second read data respectively. Subsequently, a logic circuit is provided for performing logic operations to compare the first read data with the second read data, thereby generating a random code.

Yet another embodiment of the present disclosure is to provide a PUF device, the PUF device includes the random code generator as described above, wherein the random code generator includes a plurality of resistive switch elements.

According to the above embodiments, a random code generator and the fabricating method thereof and a device applying the same. The random code generator includes at least one resistive switch element, a control circuit and a logic circuit. The control circuit is electrically connected to the at least one resistive switch element and is used to perform a forming step on the at least one resistive switch element; to perform a writing step on the at least one resistive switch element with a preset voltage; and to perform two resistance reading steps on the at least one resistive switch element to obtain a first read data and a second read data respectively. The logic circuit is electrically connected to the control circuit and is used for performing a logic operation to compare the first read data with the second read data, thereby generating a random code. In some embodiments of the present disclosure, the random code generator can be used as a PUF device of a semiconductor chip to prevent data stored in the semiconductor chip from being stolen.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1A is a circuit diagram illustrating the configuration of the random code generator, according to one embodiment of the present disclosure;

FIG. 1B is a schematic diagram illustrating the partial configuration of the random code generator, according to one embodiment of the present disclosure;

FIG. 2A is a circuit diagram of a logic circuit, according to one embodiment of the present disclosure; and

FIG. 2B is a timing diagram illustrating the pulse of the writing steps and the reading steps performed by the control circuit as well as that of the logic operation performed by the logic circuit, in the random code generator.

### DETAILED DESCRIPTION

The embodiments as disclosed below provide a random code generator and the fabricating method thereof as well as a device applying the same used to generate a unique random code for preventing data stored in the semiconductor chip from being stolen. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

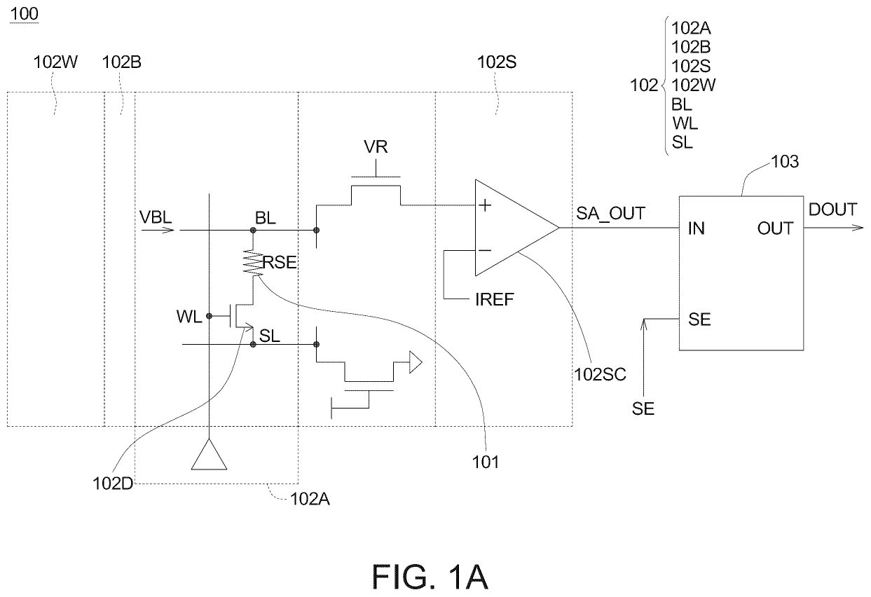

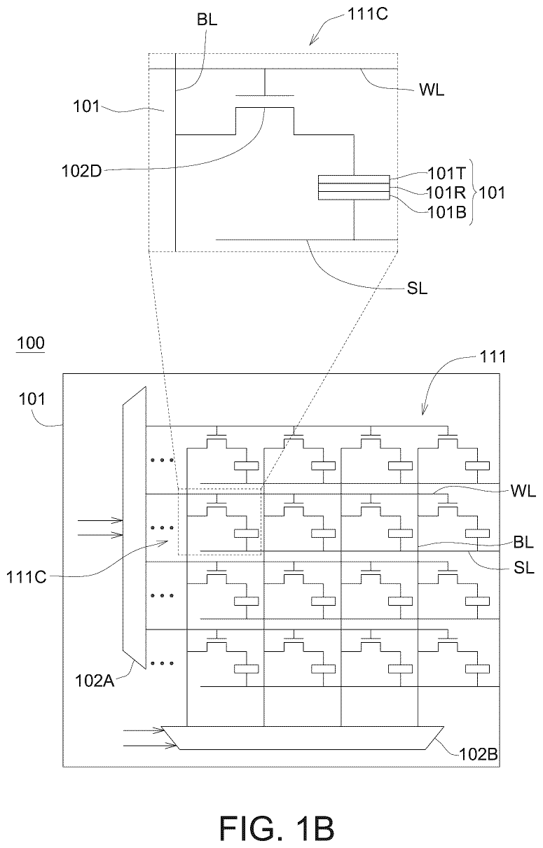

FIG. 1A is a circuit diagram illustrating the configuration of the random code generator 100, according to one embodiment of the present disclosure; and FIG. 1B is a schematic diagram illustrating the partial configuration of the random code generator 100, according to one embodiment of the present disclosure. In some embodiments of the present disclosure, the random code generator 100 includes at least one resistance switch element 101, a control circuit 102 and a logic circuit 103. The control circuit 102 is electrically connected to the resistance switch element, and the logic circuit 103 is electrically connected to the control circuit 102.

In some embodiments of the present disclosure, the random code generator 100 can be formed on a semiconductor substrate 110 by a standard semiconductor process. The semiconductor substrate 110 may be, for example, a silicon-containing substrate, such as a silicon wafer, silicon-on-insulator (SOI), or other suitable semiconductor substrates. In the present embodiment, the semiconductor substrate 101 may be a silicon wafer. The resistance switch element 101, the control circuit 102 and the logic circuit 103 are respectively formed on the silicon wafer together with other integrated circuit elements by a standard semiconductor processes.

In the present embodiment, the random code generator 100 includes a plurality of resistance switch elements 101, and each of the plurality of resistance switch elements 101 may be a resistive random-access memory (ReRAM or RRAM) unit.

As shown in FIG. 1B, each of the plurality of resistance switch elements 101 includes an upper electrode layer 101T, a resistance switching layer 101R and a lower electrode layer 101B. The materials constituting the upper electrode layer 101T and the lower electrode layer 101B may be the same or different. For example, in some embodiments of the present disclosure, the material constituting the upper electrode layer 101T and the lower electrode layer 101B can be selected from a group consisting of tungsten, titanium nitride (TiN), tantalum nitride (TaN), copper (Cu), aluminum (Al), gold (Au), silver (Ag), platinum (Pt), titanium (Ti), iridium (Ir) and any combination thereof. In the present embodiment, the material constituting the upper electrode layer 101T and the lower electrode layer 101B may be a composite metal layer consisting of TiN/TaN/Pt/Ir.

The material constituting the resistance switching layer 101R may be a transition metal oxide (TMO) or a phase change material. The transition metal oxide can be, for example, tantalum oxide (TaOx), titanium oxide (titanium oxide), nickel oxide (nickel oxide), hafnium oxide (HfOx), zirconium oxide (ZrOx), tungsten oxide (WOx), zinc oxide (ZnOx), aluminum oxide (AlOx), molybdenum oxide (MnOx), copper oxide (CuOx) or any combination thereof. The phase change material may be, for example, a chalcogenide (such as, germanium antimony telluride (GexSbyTez, where x, y and z may be integers, GST)), silver indium antimony telluride (AgInSbTe), or a combination thereof. In the present embodiment, the resistance switching layer 101R may include tantalum pentoxide (Ta₂O₅).

The control circuit 102 includes a write driver 102W, a row decoder 102A, a column decoder 102B, a plurality of bit lines BL, a plurality of control transistors 102D, a plurality of word lines WL, and a plurality of power lines SL. Each control transistor 102D corresponds to a resistance switch element (ReRAM unit) 101. The source of each control transistor 102D is electrically connected to a corresponding bit line BL; the drain of the control transistor 102D is electrically connected to the upper electrode layer 101T of the corresponding resistance switch element 101; the gate of the control transistor 102D is electrically connected to a corresponding word line WL; the lower electrode layer 101B of the resistance switch element 101 is electrically connected to a corresponding power line SL, thereby forming a ReRAM cell 111C with a one-transistor and one-resistor (1T1R) structure.

The plurality of bit lines BL and a plurality of word lines WL are perpendicularly intersecting each other; one end of each bit line BL is electrically connected to a row decoder 102A, and the other end is electrically connected to the source of a corresponding control transistor 102D in a plurality of ReRAM cells 111C arranged in the same row; one end of each word line WL is electrically connected to a column decoder 102B, and the other end is electrically connected to the gate of a corresponding control transistors 102D in a plurality of ReRAM cells 111C arranged in the same column. Thereby these plurality of ReRAM cells 111C, the bit lines BL, the word lines WL, the row decoder 102A and the column decoder 102B together construct a ReRAM cell array 111.

It should be appreciated that although the random code generator 100, in the present embodiment, merely includes one single ReRAM cell array 111, but the structure and arrangement of the random code generator 100 are not limited thereto. Any structure and arrangement that can address, initialize, write and read at least one resistance switch element 101 through the control circuit 102 does not exceed the spirit and scope of the embodiments described in the present disclosure.

In the embodiment of the present disclosure, the control circuit 102 is used to perform an initialization step on the selected (addressed) resistance switch element (ReRAM unit) 101; then perform a writing step on the selected (addressed) resistance switch element (ReRAM unit) 101 with a preset voltage; and then perform two resistance reading steps on the resistance switch element (ReRAM unit) 101 to obtain a first read data 1stRD and a second read data 2ndRD. The logic circuit 103 is electrically connected to the control circuit 102 for performing a logic operation to compare the first read data 1stRD and the second read data 2ndRD of the selected resistance switch element (ReRAM unit), thereby generating a random code DOUT.

In some embodiments of the present disclosure, the initialization of the selected resistance switch element (ReRAM unit) 101 includes steps as follows: The row decoder 102A and the column decoder 102B in the control circuit 102 are used to address the plurality of resistance switch elements (ReRAM units) 101 in the ReRAM cell array 111 through the bit line BL, the word line WL and the control transistor 102D. Then one of the resistance switch elements 101 is selected according to the address, and at least one initialization pulse is applied to the selected resistance switch element (ReRAM unit) 101, so that the selected resistance switch element (ReRAM unit) 101 is converted from an original high-resistance state (HRS) to a low-resistance state (LRS) that is easier to power on.

For example, in the present embodiment, a forward voltage (e.g., about +3V to +5V) may be applied to the selected resistance switch element (ReRAM unit) 101 to form a conductive filament in the resistance switching layer 101R of the selected resistance switch element (ReRAM unit) 101, so that the conductivity between the upper electrode layer 101T and the lower electrode layer 101B of the initialized resistance switch element (ReRAM unit) 101 is higher than that before initialization.

In some embodiments of the present disclosure, the writing step of the selected (addressed) resistance switch element (ReRAM unit) 101 includes using the write driver 102W of the control circuit 102 to apply at least one write pulse VBL, having an electrical property opposite to the initialization pulse and a voltage (e.g. a voltage between 2V and 3V) whose absolute value is substantially smaller than that of the initialization pulse, to the selected resistance switch element (ReRAM unit) 101 through the corresponding bit line BL, so as to change the selected resistance switch element (ReRAM unit) 101 from the low resistance state after initialization to a high resistance state again.

In the embodiments of the present disclosure, the voltage of the write pulse VBL is a preset value, which can make the resistance variation probability of the selected resistance switch element (ReRAM unit) 101 greater than or equal to 50%. The so-called resistance variation probability refers to the probability that the first read data 1stRD varies (differs) from the second read data 2ndRD when the resistance reading steps of the selected resistance switch element (ReRAM unit) 101 are repeatedly read several times.

For example, in the present embodiment, the control circuit 102 further includes a sensing amplifier circuit 102S, which is electrically connected to the ReRAM cell array 111, and is used to read (sense) the resistance value of the selected resistance switch element (ReRAM unit) 101 during the resistance reading steps and output a read data. When the resistance reading steps of the selected resistance switch element (ReRAM unit) 101 are performed, the power line SL of the control circuit 102 provides a ground voltage (e.g., 0.0V) to the selected resistance switch element (ReRAM unit) 101, and the sense amplifier circuit 102S provides a reference current (reference resistance) IREF. Since the read voltage (e.g., a voltage between VDD/2 and VDD) is set lower than the voltage of the write pulse VBL, thus the resistance state of the selected resistance switch element (ReRAM unit) 101 remains unchanged during the reading step, and a read current is generated. The read current and the reference current (reference resistance) IREF are input into the comparator 102SC of the sense amplifier circuit 102S, so as to obtain read data representing the resistance state of the selected resistance switch element (ReRAM unit) 101.

For example, if the read current from the selected resistance switch element (ReRAM unit) 101 is higher than the reference current (or reference resistance) IREF, it means that the selected resistance switch element (ReRAM unit) 101 is in a low resistance state. The comparator 102SC outputs a read data representing a low resistance state, such as “0”. On the contrary, if the read current from the selected resistance switch element (ReRAM unit) 101 is lower than the reference current (reference resistance) IREF, it means that the selected resistance switch element (ReRAM unit) 101 is in a high resistance state. The comparator 102SC outputs a read data representing a high resistance state, such as “1”.

The reference current (reference resistance) IREF and the voltage of the applied write pulse VBL for performing the reading steps on the selected resistance switch element (ReRAM unit) 101 can be determined by simulation or experiments, in refereeing the resistance state of a reference resistance switch element (ReRAM unit) made of the same or similar material, size (for example, thickness, area, etc.) and/or manufacturing parameters as that of the selected resistance switch element (ReRAM unit) 101, under different write pulse VBL voltages.

For example, in the present embodiment, after a preset write pulse (with a voltage less than 2V) is applied to the reference resistance switch element (ReRAM unit), the repeated two reading steps may produce in the following six possible reading results as described in Table 1:

| | first | second | first | second | |
|---|---|---|---|---|---|
| reading | read | read | read data | read data | |
| results | current | current | 1stRD | 2ndRD | probability |
| I | >IREF | >IREF | 1 | 1 | ~12.5% |
| II | <IREF | >IREF | 0 | 1 | ~25.0% |
| III | <IREF | <IREF | 0 | 0 | ~12.5% |
| IV | >IREF | >IREF | 1 | 1 | ~12.5% |
| V | >IREF | <IREF | 1 | 0 | ~25.0% |
| VI | <IREF | <IREF | 0 | 0 | ~12.5% |

The occurrence probability of the above six reading conditions can be obtained through multiple simulations or experiments. The current (resistance) and write pulse of the reading results II and V, where the resistance states of the repeated two reading steps (i.e., the first read current and the second read current are respectively greater than and less than the reference current IREF) are inconsistent and the sum of the occurrence probability of these two reading results is greater than 50%, are selected to serve as the reference current (reference resistance) IREF and the write pulse VBL applied to the selected resistance switch element (ReRAM unit) 101.

When the selected write pulse VBL is used to write the selected resistance switch element (ReRAM unit) 101, and the repeated two reading steps is performed on the selected resistance switch element (ReRAM unit) 101, the first read data 1stRD and the second read data 2ndRD can be obtained.

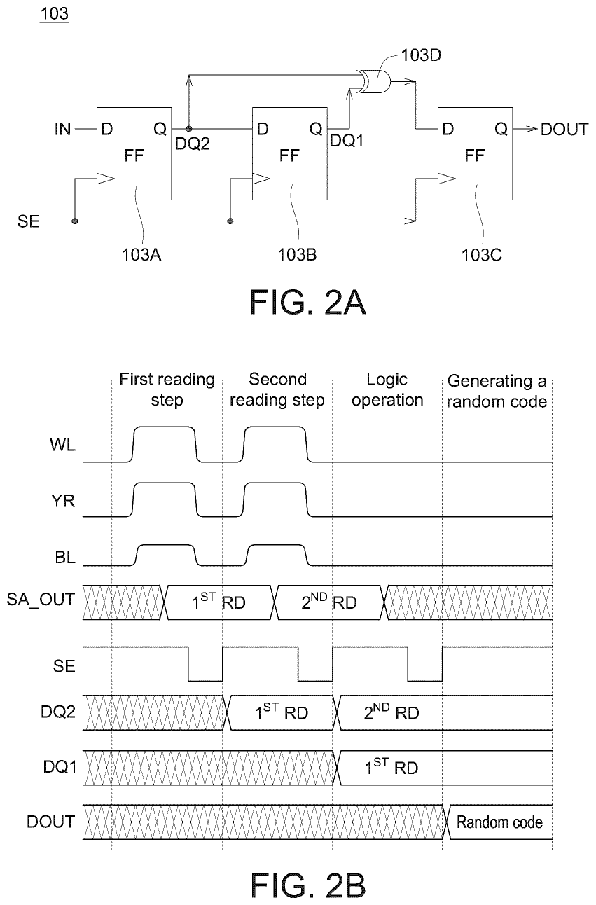

FIG. 2A is a circuit diagram of the logic circuit 103, according to one embodiment of the present disclosure; and FIG. 2B is a timing diagram illustrating the pulse of the writing steps and the reading steps performed by the control circuit 102 as well as that of the logic operation performed by the logic circuit 103, in the random code generator. In the present embodiment, the logic circuit 103 includes three flip-flops (FF) 103A, 103B and 103C and an exclusive-OR gate (XOR gate) 103D.

Three of the flip-flops 103A, 103B and 103C receive the scan enable signal SE respectively. The D input terminal IN of the flip-flop 103A is electrically connected to the output terminal SA_OUT of the comparator 102SC of the control circuit 102. The Q output terminal of the flip-flop 103A is electrically connected to the A input terminal of the XOR gate 103D and the D input terminal of the flip-flop 103B respectively. The Q output terminal of the flip-flop 103B is electrically connected to the B input terminal of the XOR gate 103D. The D input terminal of the flip-flop 103C is electrically connected to the output terminal of the XOR gate 103D. The first read data 1stRD and the second read data 2ndRD of the selected resistance switch element (ReRAM unit) 101 can generate a random code DOUT through the logic operation of the logic circuit 103, and output from the Q output terminal of the flip-flop 103C.

However, it should be appreciated that the configuration of the logic circuit 103 is not limited thereto. Any circuit configuration that can perform a logic operation to compare the first read data 1stRD and the second read data 2ndRD of the selected resistance switch element (ReRAM unit) 101 to generate a code does not exceed the spirit and scope of the logic circuit 103 as described in the present disclosure.

Since after being written with a preset voltage, the selected resistance switch element (ReRAM unit) 101 has a resistance variation probability of more than 50% as repeatedly read, thus the relationship between the first read data 1stRD and the second read data 2ndRD, which are read twice repeatedly, becomes random. After the logic operation of the logic circuit 103, a random code DOUT can be generated by comparing the first read data 1stRD and the second read data 2ndRD.

A set of unique random codes can be obtained by controlling the control circuit 102 and the logic circuit 103 to repeat the above steps in a predetermined order subject on the plurality of resistance switch element (ReRAM unit) 101 in the ReRAM cell array 111. Using this set of (at least two) unique random codes to form challenge response pairs (CRPs) or fingerprints, a PUF can be provided. In some embodiments of the present disclosure, the processing steps for fabricating the random code generator 100 can be integrated into a standard process of a semiconductor chip. Such that the random code generator 100 can sever as a PUF device of the semiconductor chip to prevent the data stored in the semiconductor chip from being stolen.

According to the above embodiments, a random code generator and the fabricating method thereof and a device applying the same. The random code generator includes at least one resistive switch element, a control circuit and a logic circuit. The control circuit is electrically connected to the at least one resistive switch element and is used to perform a forming step on the at least one resistive switch element; to perform a writing step on the at least one resistive switch element with a preset voltage; and to perform two resistance reading steps on the at least one resistive switch element to obtain a first read data and a second read data respectively. The logic circuit is electrically connected to the control circuit and is used for performing a logic operation to compare the first read data with the second read data, thereby generating a random code. In some embodiments of the present disclosure, the random code generator can be used as a PUF device of a semiconductor chip to prevent data stored in the semiconductor chip from being stolen.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A random code generator, comprising:
at least one resistive switch element,
a control circuit, electrically connected to the at least one resistive switch and used for:
performing a forming step on the at least one resistive switch element;
performing a writing step on the at least one resistive switch element with a preset voltage; and
performing two resistance reading steps on the at least one resistive switch element to obtain a first read data and a second read data respectively; and
a logic circuit, electrically connected to the control circuit and used for performing a logic operation to compare the first read data with the second read data, thereby generating a random code.

2. The random code generator according to claim 1, wherein the at least one resistive switch element comprises at least one resistive random-access memory (ReRAM) unit.

3. The random code generator according to claim 2, wherein the preset voltage can make a resistance variation probability of the at least one ReRAM unit greater than or equal to 50%.

4. The random code generator according to claim 2, wherein the at least one ReRAM unit comprises a dielectric layer made of a material comprising tantalum oxide (TaOx), and the preset voltage is less than 2V.

5. The random code generator according to claim 2, wherein the control circuit comprises:
a bit lines, electrically connected to the at least one ReRAM unit;
a control transistor, electrically connected to the at least one ReRAM unit; and
a word line, electrically connected to the control transistor.

6. The random code generator according to claim 1, wherein the logic circuit comprises an exclusive-OR gate (XOR gate).

7. A method for fabricating a random code generator, comprising:
providing at least one resistive switch element;
providing a control circuit electrically connected to the at least one resistive switch element for:
performing a forming step on the at least one resistive switch element;
performing a writing step on the at least one resistive switch element with a preset voltage; and
performing two resistance reading steps on the at least one resistive switch element to obtain a first read data and a second read data respectively; and
providing a logic circuit for performing a logic operation to compare the first read data with the second read data, thereby generating a random code.

8. The method according to claim 7, wherein the at least one resistive switch element comprises at least one ReRAM unit.

9. The method according to claim 8, wherein the control circuit comprises:
a bit lines, electrically connected to the at least one ReRAM unit;
a control transistor, electrically connected to the at least one ReRAM unit; and
a word line, electrically connected to the control transistor.

10. The method according to claim 8, wherein the logic circuit comprises an XOR gate.

11. The method according to claim 8, wherein the at least one ReRAM unit comprises a dielectric layer made of a material comprising TaOx.

12. A physically unclonable function (PUF) device, comprising:
a random code generator, comprising:
at least one resistive switch element,
a control circuit, electrically connected to the at least one resistive switch and used for:
performing a forming step on the at least one resistive switch element;
performing a writing step on the at least one resistive switch element with a preset voltage; and
performing two resistance reading steps on the at least one resistive switch element to obtain a first read data and a second read data respectively; and
a logic circuit, electrically connected to the control circuit and used for performing a logic operation to compare the first read data with the second read data, thereby generating a random code.

13. The PUF device according to claim 12, wherein the at least one resistive switch element comprises at least one ReRAM unit.

14. The PUF device according to claim 13, wherein the preset voltage can make a resistance variation probability of the at least one ReRAM unit greater than or equal to 50%.

15. The PUF device according to claim 13, wherein the at least one ReRAM unit comprises a dielectric layer made of a material comprising TaOx, and the preset voltage is less than 2V.

16. The PUF device according to claim 13, wherein the control circuit comprises:
a bit lines, electrically connected to the at least one ReRAM unit;
a control transistor, electrically connected to the at least one ReRAM unit; and
a word line, electrically connected to the control transistor.

17. The PUF device according to claim 12, wherein the logic circuit comprises an XOR gate.
